(19) United States
(12) Patent Application Publication
(10) Pub. No.: US 2012/0042921 A1
(43) Pub. Date: Feb. 23, 2012

(54) Method for manufacturing thermoelectric module and thermoelectric module manufactured from the same

(75) Inventors: Yong Suk Kim, Yongin-si (KR); Sung Ho Lee, Seongnam-si (KR); Young Soo Oh, Seongnam-si (KR); Tae Kon Koo, Seoul (KR)

(73) Assignee: SAMSUNG ELECTRO-MECHANICS CO., LTD., Suwon (KR)

(21) Appl. No.: 12/926,671

(22) Filed: Dec. 2, 2010

(30) Foreign Application Priority Data
Aug. 18, 2010 (KR) 10-2010-0079824

(51) Int. Cl. H01L 35/20; H05K 13/00; H01L 35/22

(52) U.S. Cl. 136/200; 29/592.1; 136/201

(57) ABSTRACT

The present invention provides a method for manufacturing a thermoelectric module and a thermoelectric module manufactured from the same. The method includes the steps of: forming each of first and second green laminates; forming first and second preliminary electrodes by printing a conductive paste on each of the first and second green laminates; disposing thermoelectric elements on any one of the first and second preliminary electrodes; stacking the first and second green laminates in such a manner that the thermoelectric elements are interposed between the first and second preliminary electrodes; and firing the stacked first and second green sheet laminates, thereby forming the first and second electrodes, and first and second ceramic substrates, and simultaneously bonding the first ceramic substrate to the first electrode, the first and second electrodes to the thermoelectric elements, and the second ceramic substrate to the second electrode.

### CROSS-REFERENCE TO RELATED APPLICATIONS

This application claims the benefit under 35 U.S.C. Section [120, 119, 119(e)] of Korean Patent Application Serial No. 10-2010-0079824, entitled “Method For Manufacturing Thermoelectric Module And Thermoelectric Module Manufactured From The Same” filed on Aug. 18, 2010, which is hereby incorporated by reference in its entirety into this application.

### BACKGROUND OF THE INVENTION

1. Field of the Invention

The present invention relates to a method for manufacturing a thermoelectric module; and, more particularly, to a method for manufacturing a thermoelectric module with electrodes and substrates which are bonded to one another by one-time firing process, and a thermoelectric module manufactured from the same.

2. Description of the Related Art

A rapidly increased use in fossil energies causes global warming and energy exhaustion. In order to solve these problems, many studies have recently been conducted on a thermoelectric module that can effectively use energies.

In general, a thermoelectric module may be used as a power generator employing a seebeck effect and a cooling system employing a peltier effect. Herein, the seebeck effect refers to a principle where an electromotive force is generated when temperature differences are given to each end of a thermoelectric device, and the peltier effect refers to a principle where heat is released at one end and absorbed at the other end thereof when a direct current is applied to a thermoelectric device.

Herein, thermoelectric modules may include first and second electrodes formed on the inner surfaces of two substrates, and thermoelectric elements interposed between the first and second electrodes.

In order to form the thermoelectric module, a metal material is coated or printed on each of the upper and lower substrates to thereby form first and second electrodes, and then a reflow process is performed where through a solder, the lower substrate, the first electrode, and the thermoelectric elements, and the second electrode are bonded to the first electrode, the thermoelectric element, the second electrode, and the upper substrate, respectively.

As such, because the formation of the thermoelectric module requires so many processes, there may be a rising cost of the processes in the thermoelectric module.

Also, precision-failure of the pattern and absence of bonding surface areas between substrates and electrodes may cause the electrodes and the substrates incompletely bonded to each other. Further, since the flatness of the substrate may be reduced in the process of forming the electrodes on the substrate, bonding-failure and contact-resistance between the electrodes and the thermoelectric elements may be increased. At this time, the bonding-failure between respective components of the thermoelectric module (i.e., substrates and electrodes, or electrodes and thermoelectric elements) may result in a reduction of the performance index of the thermoelectric module. In addition to this, degradation caused by thermal impact and inner moisture may be rapidly produced, which results in a reduction in the reliability of the thermoelectric module.

Therefore, in order to solve the problem occurring in the conventional thermoelectric module, there is a need for a new manufacturing process for implementing a reduction in the number of processes, as well as in the bonding-failure between respective components, thereby securing the reliability of the thermoelectric module.

### SUMMARY OF THE INVENTION

The present invention has been proposed in order to overcome the above-described problems and it is, therefore, an object of the present invention to provide a method for manufacturing a thermoelectric module which includes substrates and electrodes bonded by a collective firing process, so that it is possible to reduce the number of processes, and thus to secure the reliability of the thermoelectric module, and a thermoelectric module manufactured from the method.

In accordance with one aspect of the present invention to achieve the object, there is provided a method for manufacturing a thermoelectric module including the steps of: forming each of first and second green laminates; forming first and second preliminary electrodes by printing a conductive paste on each of the first and second green laminates; disposing thermoelectric elements on any one of the first and second preliminary electrodes; stacking the first and second green laminates in such a manner that the thermoelectric elements are interposed between the first and second preliminary electrodes; and firing the stacked first and second green sheet laminates, thereby forming the first and second electrodes, and first and second ceramic substrates, and simultaneously bonding the first ceramic substrate to the first electrode, the first and second electrodes to the thermoelectric elements, and the second ceramic substrate to the second electrode.

Herein, the method includes a step of forming a shrinkage constraint layer on an outer surface of each of the first and second green laminates, between the step of forming the first and second green laminates and the step of forming the first and second preliminary electrodes.

Also, the shrinkage constraint layer is removed after the step of firing the stacked first and second green laminates.

Also, the stacked first and second green laminates may be fired by a pressurizing/firing process.

Also, in the step of forming the first and second green laminates, the shrinkage constraint layer is interposed between the stacked green sheets for each of the first and second green laminates.

Also, each of the first and second green laminates is provided with first and second grooves in which the first and second preliminary electrodes are buried, between the step of forming the first and second green laminates and the step of forming the first and second preliminary electrodes.

In accordance with another aspect of the present invention to achieve the object, there is provided a thermoelectric module including: first and second ceramic substrates which face each other; first and second electrodes which are interposed between the first and second ceramic substrates and are bonded on inside surfaces of the first and second ceramic substrates by themselves, the first and second electrodes being stacked in a single layer; and thermoelectric elements which are interposed between the first and second electrodes and are bonded to the first and second electrodes by self-bonding of the first and second electrodes.

Also, the inner surfaces of the first and second ceramic substrates each are provided with grooves to bury the first and second electrodes.

Also, each of the first and second electrodes includes Sn, and further includes any one of Cu, Au, Ag, Bi, Ni, Sb, and Zr.

Also, the first and second ceramic substrates have outside surfaces each of which has a shrinkage constraint layer formed thereon.

Also, each of the shrinkage constraint layers are provided between the ceramic substrates.

Also, the shrinkage constraint layer includes at least one of Al₂O₃, MgO, ZrO₂, and TiO₂.

Also, each of the first and second ceramic substrates is formed with ceramic sheets stacked in multiple layers.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 4 are cross-sectional views showing a process of manufacturing a thermoelectric module in accordance with a first embodiment of the present invention, respectively; and

FIGS. 6 to 9 are cross-sectional views for explaining a process of manufacturing a thermoelectric module in accordance with a second embodiment of the present invention, respectively.

### DETAILED DESCRIPTION OF THE PREFERABLE EMBODIMENTS

Embodiments of a thermoelectric module in accordance with the present invention will be described in detail with reference to the accompanying drawings. The embodiments herein are rather introduced to provide easy and complete understanding of the scope and spirit of example embodiments.

The invention, however, may be embodied in various different forms, and should not be construed as being limited only to the illustrated embodiments. Throughout the drawings and written description, like reference numerals will be used to refer to like or similar elements. Further, the dimensions of layers and regions are exaggerated for clarity of illustration.

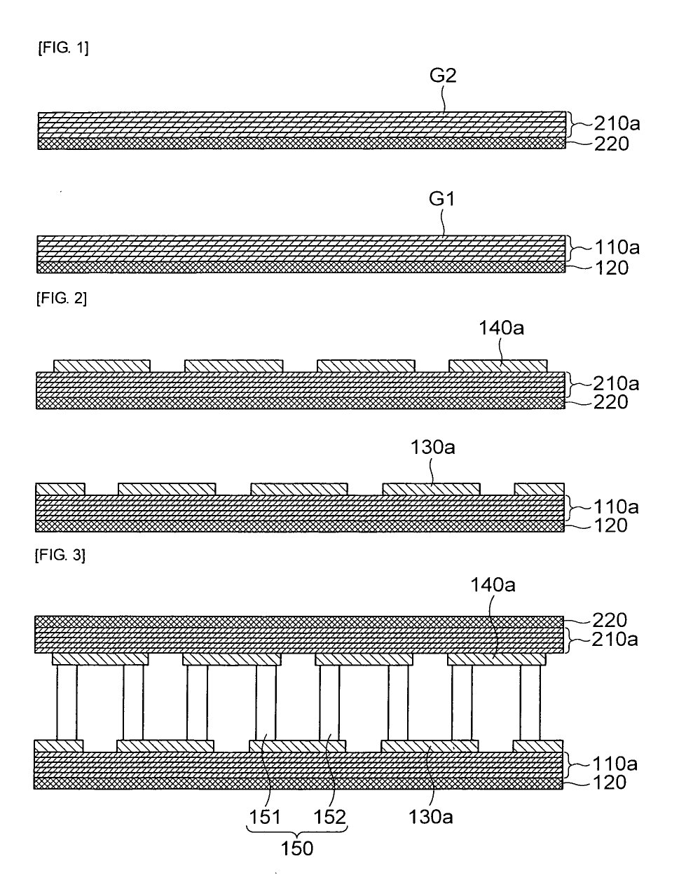

FIGS. 1 to 4 are cross-sectional views showing a process of manufacturing the thermoelectric module in accordance with a first embodiment of the present invention, respectively.

Referring to FIG. 1, in order to manufacture the thermoelectric module, first and second green sheet laminates 110a and 210a are formed.

Herein, in order to form the first green sheet laminate 110a, the first green sheets G1 are provided. Herein, the first green sheets G1 may be formed by be subjected to coating and drying processes including a ceramic powder, binder resin, and solvent. Thereafter, first green sheets G1 are stacked in multiple layers to thereby form the first green sheet laminate 110a.

The number of the first green sheets constituting the first green sheet laminate 110a is not limited by the embodiment of the present invention. Those skilled in the art may be manufactured through various manners in consideration of the process conditions and applications of the thermoelectric module.

In addition, the first green sheet laminate 110a is formed, and then a first shrinkage constraint layer 120 may be further formed on the outermost layer of the first green sheet laminate 110a.

Herein, the first shrinkage constraint layer 120 is not fired in a firing process of the first green sheet laminate 110a to be later described. That is, the first shrinkage constraint layer 120 fails to be deformed in the firing process of the first green sheet laminate 110a to be later described. Thus, the first shrinkage constraint layer 120 may play a role of preventing the respective green sheets from being shrunk during the firing process. Thus, it is possible to prevent the flatness of the thermoelectric module from being reduced due to the deformation (e.g., warpage) in the firing process of the first green sheet laminate 110a.

The first shrinkage constraint layer 120 may be formed of a material with a higher firing temperature than that of the ceramic powder constituting the green sheet G1. As for the material of the first shrinkage constraint layer 120, Al₂O₃, MgO, ZrO₂, and TiO₂ may be exemplified.

The first shrinkage constraint layer 120 is formed to be shrinkage constraint sheets, and then the shrinkage constraint sheets are stacked on the first green sheet laminates 110a, thereby forming the first shrinkage constraint layer 120. However, the method for formation of the first shrinkage constraint layer 120 is not limited to the embodiment of the present invention. Also, the first shrinkage constraint layer 120 may be formed by a deposition scheme.

Although it has been illustrated in the embodiment of the present invention that the first shrinkage constraint layer 120 is provided on the outermost layer of the first green sheet laminate 110a, the present invention is not limited thereto. The first shrinkage constraint layer 120 may be disposed inside the first green sheet laminate 110a. That is, the first shrinkage constraint layer 120 may be interposed between the first green sheets G1 formed by a stacking process of the first green sheets G1 for formation of the first green sheet laminate 110a.

The second green sheet laminate 210a may be formed by stacking second green sheets G2. The first and second green laminates 110a and 210a may be formed through the same material and the same process as each other, and thus a process of manufacturing the green sheet laminate 210a will be omitted.

Also, the second shrinkage constraint layer 220 is formed on the outermost layer of the second green sheet laminate 210a, thereby preventing the second green sheet laminate 210a from being shrunk in a firing process to be later described.

Referring to FIG. 2, the first and second green sheet laminates 110a and 210a are formed, and then first and second preliminary electrodes 130a and 140a are formed on the first and second green sheet laminates 110a and 210a, respectively.

Herein, a conductive paste may be printed on the first green sheet laminate 110a to thereby form the first preliminary electrode 130a. Herein, the conductive paste may include Sn, and may further include any one of Cu, Au, Ag, Bi, Ni, Sb, and Zr. At this time, Sn may play a role of improving the bonding between the first ceramic substrate 110 and the first electrode 130, and between the first electrode 130 and the thermoelectric elements 150, in the firing process.

A conductive paste may be printed on the second green sheet laminate 210a to thereby form the second preliminary electrode 140a.

The preliminary second electrode 140a may include Sn, and may further include any one of Cu, Au, Ag, Bi, Ni, Sb, and Zr. Herein, the preliminary second electrode 140a may be formed of the same material as that of the first preliminary electrode 130a, or may be formed of a different material from that of the preliminary electrode 130a.

Herein, in case where the first and second green sheet laminates 110a and 210a are disposed to face each other, the first and second preliminary electrodes 130a and 140a may be formed to be partially overlapped with each other.

Referring to FIG. 3, the first and second preliminary electrodes 130a and 140a are formed, and then the thermoelectric elements 150 are disposed on at least one of the first and second preliminary electrodes 130a and 140a. For example, the thermoelectric elements 150 may be disposed on the first preliminary electrode 130a. Herein, the thermoelectric elements 150 may include a P-type semiconductor 151 and an N-type semiconductor 152. Herein, the P-type semiconductor 151 and the N-type semiconductor 152 may be alternately disposed on the same plane.

After the thermoelectric elements 150 are disposed, on one preliminary electrode with the thermoelectric elements 150 disposed thereon from among the first and second preliminary electrodes 130a and 140a, a green sheet laminate with the other preliminary electrode is stacked. For example, the second green sheet laminate 210a is stacked above the first green sheet laminate 110a in such a manner that the thermoelectric elements 150 and the second electrode 140 are contacted to each other.

At this time, one pair of the P-type semiconductor 151 and the N-type semiconductor 152 is electrically connected by the first preliminary electrode 130a disposed on its lower surface. Another pair of the P-type semiconductor 151 and the N-type semiconductor 152 adjacent to the one is electrically connected by the preliminary second electrode 140a disposed on its upper surface.

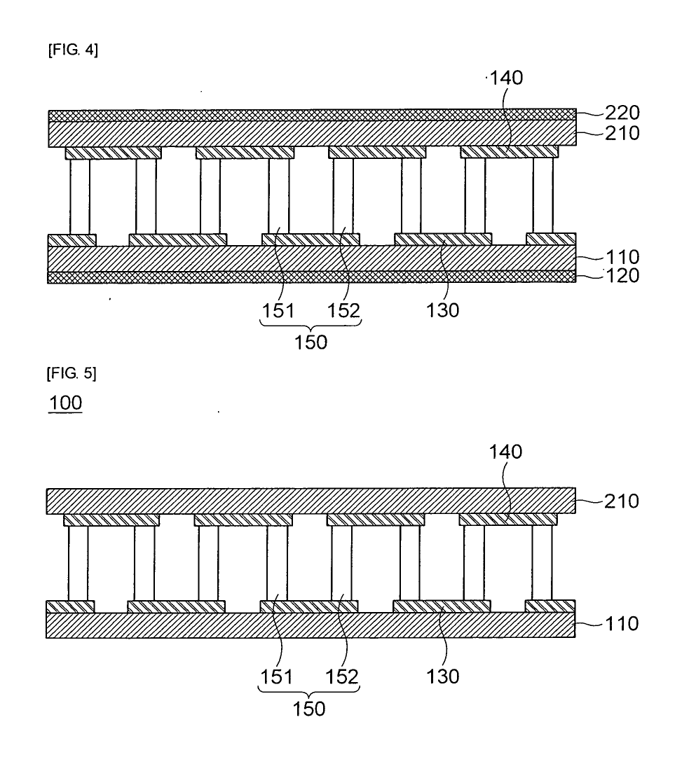

Referring to FIG. 4, after the first and second green sheet laminates 110a and 210a are stacked one on above, the stacked first and second green sheet laminates 110a and 210a are subjected to a firing process to thereby form the thermoelectric module 100. That is, the first and second green sheet laminates 110a and 210a are subjected to a firing process, thereby forming first and second ceramic substrates 110 and 210 and first and second electrodes 130 and 140. Simultaneously with this, the first ceramic substrate 110, the first electrode 130, the thermoelectric elements 150, the second electrode 140 may be collectively bonded to the first electrode 130, the thermoelectric element 150, the second electrode 140, and the second ceramic substrate 210, respectively.

The firing process of the stacked first and second green sheet laminates 110a and 210a may be achieved through a pressurizing/firing process, so as to effectively prevent the shrinkage of the first and second green sheet laminates 110a and 210a. At this time, in case where the first and second shrinkage constraint layers are provided in the first and second green sheet laminates 110a and 210a, respectively, it is unnecessary to perform the pressurizing/firing process. This is because that the shrinkage constraint layers disposed within the green sheet laminates play a role of effectively preventing deformation of each of the first and second green sheet laminates 110a and 210a.

Referring to FIG. 5, after the thermoelectric module is manufactured, a process may be further performed where the first and second shrinkage constraint layers 120 and 220 are removed. As for the method for removing the first and second shrinkage constraint layers 120 and 220, a polishing process or a crushing process employing ultrasound may be used.

However, although it has been illustrated in the embodiment of the present invention that the first and second shrinkage constraint layers 120 and 220 are removed, the present invention is not limited thereto. Alternatively, the first and second shrinkage constraint layers 120 and 220 may be left. At this time, the first and second shrinkage constraint layers 120 and 220 may further play a role of a protecting material for protecting surfaces of the thermoelectric module until completion of the manufacturing process of the thermoelectric module.

Also, a process for connecting one end of each in the first electrode 130 and the second electrode 140 to an external power source may be further performed so that the thermoelectric module 100 may supply/receive a power to/from the external power source.

Also, a process for attaching a heat sink on one surface of the thermoelectric module 100, that is, any one surface of the first and second ceramic substrates 110 and 210, may be further performed. At this time, the thermoelectric module 100 may have stable flatness, so that it is possible to secure bonding stability between the thermoelectric module 100 and the heat sink, and thus to increase heat radiation effect.

Therefore, as in the embodiment of the present invention, respective components of the thermoelectric module may be bonded to one another even by one-time firing process, which results in a reduction of the number of processes in manufacturing the thermoelectric module.

Also, since the respective components may be bonded to one another even without a separate solder, it is possible to reduce a cost taken for materials of the thermoelectric module, as well as to form the first and second electrodes in a single layer. Thus, it is possible to improve bonding stability between the ceramic substrates, the electrodes, and the thermoelectric elements. Thus, it is possible to manufacture a thermoelectric module tolerable to a high-temperature and a high-moisture, and thermal impact. Also, it is possible to reduce contact resistance between the respective components, and thus to expect excellent heat radiant effect.

Also, the electrodes may be formed on the first and second green sheet laminates through a selective use of a wet process like a printing process and a dry process like a deposition process, so that it is possible to increase the freedom of design of the thermoelectric module.

Also, the first and second shrinkage constraint layers prevent the first and second green sheet laminates from being deformed in the firing process of the first and second green sheet laminates, so that it is possible to maintain the flatness of the thermoelectric module (i.e., ceramic substrates, electrodes, and thermoelectric elements).

With reference to FIG. 5, a thermoelectric module manufactured from the first embodiment of the present invention will be described in more detail.

Referring to FIG. 5, the thermoelectric module according to the first embodiment of the present invention may include first and second ceramic substrates 110 and 210, first and second electrodes 130 and 140, and thermoelectric elements 150. The first and second ceramic substrates 110 and 210 face each other, and the first and second electrodes 130 and 140 are bonded to the first and second ceramic substrates 110 and 210, respectively, and are formed in a single layer. The thermoelectric element 150 is interposed and bonded between the first and second electrodes 130 and 140.

Herein, the respective components of the thermoelectric module may be collectively bonded to one another by a firing process, which requires no separate bonding member like a solder. In more particular, the first ceramic substrate 110, the first electrode 130, the thermoelectric elements 150, and the second electrode 140 are collectively boned to the first electrode 130, the thermoelectric element 150, the second electrode 140, and the second ceramic substrate 210, respectively. That is, the first and second ceramic substrates 110 and 210, and the first and second electrodes 130 and 140 each may play a role of a bonding member by themselves.

Each of the first and second electrodes 130 and 140 may further include any one of Cu, Au, Ag, Bi, Ni, Sb, and Zr. The first and second electrodes 130 and 140 may be formed of the same material from each other. However, the present invention is not limited thereto, and the first and second electrodes 130 and 140 may be formed of a different material from each other. At this time, each of the first and second electrodes 130 and 140 may further include Sn for increasing the bonding property.

Also, a plurality of green sheets are stacked to thereby form green sheet laminates, and then the green sheet laminates are subjected to a firing process, thereby manufacturing the first and second ceramic substrates 110 and 210. Therefore, each of the first and second ceramic substrates 110 and 210 may be formed with a plurality of sheets formed through a firing process of a plurality of green sheets.

In the thermoelectric module 100, the first and second shrinkage constraint layers 120 and 220 may be further provided on the outermost layers of the first and second ceramic substrates 110 and 210, respectively. Herein, the first and second shrinkage constraint layers 120 and 220 may prevent the first and second ceramic substrates 110 and 210 from being deformed in the firing process in manufacturing the thermoelectric module, thereby maintaining the flatness f the thermoelectric module.

Also, the first and second shrinkage constraint layers 120 and 220 may be left after the firing process of the thermoelectric module, and thus may further perform a role of protecting the surface of the thermoelectric module.

Also, the thermoelectric module 100 may have a structure where the first and second ceramic substrates 110 and 210 each are provided with the first and second shrinkage constraint layers formed therein, so that it is possible to prevent the thermoelectric module from being deformed in the firing process even if the pressurizing/firing process is not performed. That is, the first and second ceramic substrates 110 and 210 have the first and second shrinkage constraint layers formed therein, so that it is possible to maintain the flatness of the thermoelectric module through an easy process.

In addition, although not shown in the accompanying drawings, one end in each of the first and second electrodes 130 and 140 may be connected to an external power source, so that the thermoelectric module may supply/receive a power to/from the external power source. That is, in case where the thermoelectric module 100 plays a role of a power generator, the power may be supplied to the external power source. In case where the thermoelectric module 100 plays a role of a cooling system, the power may be received from the external power source.

Therefore, in the thermoelectric module according to the embodiment of the present invention, the first and second ceramic substrates and first and second electrodes are boned to one another by one-time firing process even without a separate bonding member, and thus first and second electrodes are formed in a single layer, so that it is possible to improve bonding between the ceramic substrates, the electrodes, and the thermoelectric elements.

Thus, it is possible to secure strong tolerance to a high-temperature, a high-moisture, and a thermal impact of the thermoelectric module. Also, it is possible to reduce contact resistance between the respective components, which results in excellent heat radiation effect.

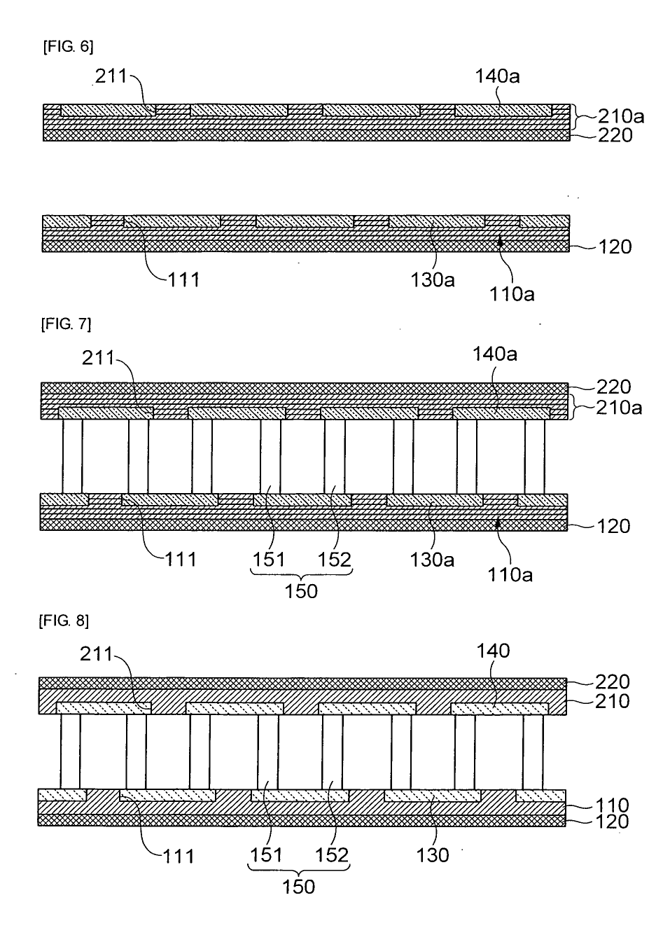

FIGS. 6 to 9 are cross-sectional views for explaining the process of manufacturing the thermoelectric module in accordance with a second embodiment of the present invention, respectively. Herein, the manufacturing process according to the second embodiment may be the same as that of the above-described first embodiment, except that grooves are formed on the first and second ceramic substrates. Therefore, the repeated description thereof will be omitted.

Referring to FIG. 6, in order to manufacture the thermoelectric module in accordance with the second embodiment of the present invention, the first and second green sheet laminates 110a and 210a are formed. The outer surfaces of the first and second green sheet laminates 110a and 210a may further include the first and second shrinkage constraint layers 120 and 220, respectively. In addition, the first and second shrinkage constraint layers 120 and 220 may be further disposed inside the first and second green sheet laminates 110a and 210a.

The first and second green sheet laminates 110a and 210a are formed, and then a plurality of first and second grooves 111 and 2111 are formed on the inside surfaces of the first and second green sheet laminates 110a and 210a, respectively. In particular, although not shown in the accompanying drawings, a mask pattern formed of a resist pattern or a laser marking is formed on the inside surface of the first green sheet laminate 110a. Thereafter, the first groove 111 is selectively formed on the first green sheet laminate 110a through the laser processing using the mask pattern. The second groove 211 is formed on the inside surface of the second green sheet laminate 210a in the same manner as in the first groove 111.

Thereafter, the first and second grooves 111 and 211 may be formed on the inside surfaces of the first and second green sheet laminates 110a and 210a, and the surfaces of the first and second green sheet laminates 110a and 210a each may be subjected to a lapping surface treatment. Thus, it is possible to improve the flatness of the first and second green sheet laminates 110a and 210a, as well as to remove impurities formed in the course of processing the first and second grooves 111 and 211. Herein, the lapping surface treatment may use at least one abrasive of Sic, alumina, and boron.

Also, after the surface-treatment is performed, a washing process and a dry process for removing organic/inorganic materials and foreign materials remaining on the first and second green sheet laminates 110a and 210a may be further performed.

Thereafter, the first and second grooves 111 and 211 are formed on the first and second green sheet laminates 110a and 210a, respectively, and then the conductive paste is filled in the first and second grooves 111 and 211, thereby forming the first and second preliminary electrodes 130a and 140a. At this time, the first and second preliminary electrodes 130a and 140a may be received the first and second grooves 111 and 211, respectively. Herein, the conductive paste includes Sn, and may further include any one of Cu, Au, Ag, Bi, Ni, Sb, and Zr.

Herein, the filling by the conductive paste may be made by a screen printing, an ink-jet printing, and a plating process. Alternatively, sputtering, E-beam scheme, CVD scheme, and a cold spray may be used.

In addition to this, the first and second preliminary electrodes 130a and 140a are formed and subjected to the lapping surface-treatment, so that it is possible to improve the flatness of the first and second green sheet laminates 110a and 210a provided with the first and second preliminary electrodes 130a and 140a.

Referring to FIG. 7, the first and second preliminary electrode 130a and 140a are formed, and then thermoelectric elements 150 are disposed on at least one of the first and second preliminary electrodes 130a and 140a. For example, the thermoelectric element 150 may be disposed on the first preliminary electrode 130a. Herein, the thermoelectric element 150 may include the P-type semiconductor 151 and the N-type semiconductor 152 which are alternately disposed.

After the thermoelectric elements 150 are disposed, on one preliminary electrode with the thermoelectric elements 150 disposed thereon from among the first and second preliminary electrodes 130a and 140a, a green sheet laminate with the other preliminary electrode is stacked. For example, the second green sheet laminate 210a is stacked on the first green sheet laminate 110a in such a manner that the thermoelectric elements 150 and the second electrode 140 are contacted to each other.

Referring to FIG. 8, after the first and second green sheet laminates 110a and 210a are stacked one on above, the stacked first and second green sheet laminates 110a and 210a are subjected to a firing process to thereby form the thermoelectric module 100. That is, by the firing process of the stacked first and second green sheet laminates 110a and 210a, it is possible to form the first and second ceramic substrates 110 and 210, and the first and second electrodes 130 and 140. Simultaneously with this, the first ceramic substrate 110, the first electrode 130, the thermoelectric elements 150, and the second electrode 140 may be collectively bonded to the first electrode 130, the thermoelectric elements 150, the second electrode 140, and the second ceramic substrate 210, respectively.

At this time, as the first preliminary electrode 130a is provided in the first groove 111 of the first green sheet laminate 110a, after having been subjected to the firing process, the first electrode 130 may be buried in the first groove 111 of the first ceramic substrate 110. Thus, it is possible to increase the boning area between the first electrode 130 and the first ceramic substrate 110, and thus to secure bonding stability between the first and second electrodes 130 and 140 and the thermoelectric elements 150. The respective components of the thermoelectric module 100 may have an improved bonding therebetween, so that it is possible to reduce the electrical resistance and heat conductivity, and thus to increase the performance index of the thermoelectric module 100. This is because the performance index of the thermoelectric module 100 is in inverse proportion to the heat conductivity, but the performance index of the thermoelectric module is in proportion to the electrical conductivity.

In addition, since the first electrode 131 is buried in the first ceramic substrate 110, the thickness of thermoelectric module may be reduced as large as that of the first electrode 131. Also, the first and second electrodes 130 and 140 are buried in the first and second substrates 110 and 210, so that it is possible to reduce thickness differences of the first and second electrodes 130 and 140 away from the first and second ceramic substrates 110 and 210, which results in good flatness of the thermoelectric module.

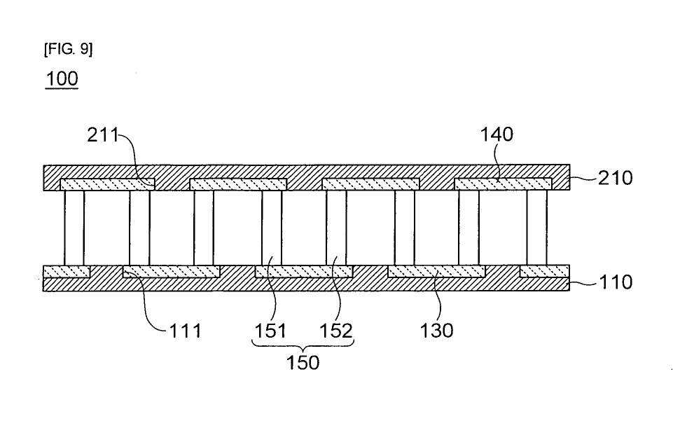

Referring to FIG. 9, the first and second shrinkage constraint layers 120 and 220 may be removed where the first and second green sheet laminates 110a and 210a are prevented from being deformed in the firing process.

In addition, although not shown in the accompanying drawings, a process for connecting one end of each in the first and second electrodes 130 and 140 to an external power source may be further performed, so that the thermoelectric module 100 may supply/receive a power to/from the external power source.

Also, a process may be further performed where the heat sink is attached on one surface of the thermoelectric module 100, that is, one surface of the first and second ceramic substrates 110 and 210. At this time, the thermoelectric module 100 maintains the flatness, so it is possible to secure bonding stability between the thermoelectric module 100 and the heat sink, which results in an increase of a heat radiation effect.

Therefore, as in the embodiment of the present invention, respective components of the thermoelectric module may be bonded to one another through one-time firing process, which results in a reduction of the number of processes required for manufacturing the thermoelectric module.

Also, as the first and second electrodes are buried into the first and second ceramic substrates, it is possible to increase areas where the first and second electrodes may be bonded to the first and second ceramic substrates, as well as to reduce the thickness differences between the first and second electrodes from the ceramic substrates. Therefore, it is possible to improve reliability of the thermoelectric module, as well as to effectively increase the performance index of the thermoelectric module.

Referring to FIG. 9, a detailed description will be given of the thermoelectric module in accordance with the second embodiment of the present invention.

Referring to FIG. 9, the thermoelectric module according to the second embodiment of the present invention may include first and second ceramic substrates 110 and 210, first and second electrodes 130 and 140, and thermoelectric elements 150. The first and second ceramic substrates 110 and 210 face each other, and the first and second electrodes 130 and 140 are bonded to the first and second ceramic substrates 110 and 210, respectively, and are formed in a single layer. The thermoelectric elements 150 are interposed and bonded between the first and second electrodes 130 and 140.

Herein, the first and second electrodes 130 and 140 may be buried in the first and second ceramic substrates 110 and 210, respectively. Thus, the first and second electrodes 130 and 140 are buried into the first and second ceramic substrates 110 and 210, so it is possible to reduce the thickness of the thermoelectric module 100. Also, it is possible to reduce thickness differences of the first and second electrodes 130 and 140 away from the ceramic substrates, which results in good flatness of the thermoelectric module 100. Further, as the bonding areas between the substrate and electrodes are increased, it is possible to secure the bonding stability between the respective components of the thermoelectric module.

The green sheet laminates are formed by stacking a plurality of green sheets, and then the green sheet laminates are subjected to a firing process, thereby manufacturing the first and second ceramic substrates 110 and 210. Therefore, each of the first and second ceramic substrates 110 and 210 may be formed with a plurality of ceramic sheets.

In addition, the thermoelectric module 100 may be further provided with the shrinkage constraint layer on the outermost layer of each in the first and second ceramic substrates 110 and 120. Also, the thermoelectric module 100 may have a structure where the insides of the first and second ceramic substrates are provided with the first and second shrinkage constraint layers, respectively.

In addition, although not shown in the accompanying drawings, one end in each of the first and second electrodes 130 and 140 may be connected to an external power source, so that the thermoelectric module may supply/receive a power to/from the external power source. That is, in case where the thermoelectric module 100 plays a role of a power generator, the thermoelectric module 100 may supply the power to the external power source. In case where the thermoelectric module 100 plays a role of a cooling system, the thermoelectric module 100 may receive the power supplied from the external power source.

Therefore, in the thermoelectric module according to the embodiment of the present invention, the first and second ceramic substrates and the first and second electrodes are collectively bonded to one another even without a separate bonding member, and thus the first and second electrodes are formed in a single layer, which results in improvement of bonding between the ceramic substrates, the electrodes, and the thermoelectric elements.

Thus, it is possible to manufacture a thermoelectric module tolerable to a high-temperature and a high-moisture, and thermal impact. Also, the contact resistance between the respective components may be reduced, but the heat conductivity may be increased, so that it is possible to increase the performance index of the thermoelectric module and to expect excellent heat radiation effect.

Also, the thermoelectric module according to the present invention has a structure where ceramic substrates can be prevented from being deformed in the firing process by using the shrinkage constraint layers provided thereon. Also, in the thermoelectric module, the electrodes are buried into the ceramic substrates, thereby reducing thickness differences of the electrodes away from the substrates, which results in improved flatness of the thermoelectric module. Thus, it is possible to increase the performance index of the thermoelectric module, as well as to secure the reliability of the thermoelectric module.

According to the thermoelectric module of the present invention, it is possible to bond respective components including substrates, electrodes, and thermoelectric elements to one another by collectively firing the substrates and the electrodes, thereby reducing the number of processes in manufacturing the thermoelectric module.

Also, according to the thermoelectric module of the present invention, it is possible to bond respective components including substrates, electrodes, and thermoelectric elements to one another by one-time firing process even without a separate solder layer, thereby implementing a reduction of material's cost and an increase of bonding the reliability between the respective components.

Also, according to the thermoelectric module of the present invention, the electrodes are buried into the substrates, so that it is possible to secure the bonding reliability between the substrates and the electrodes.

Also, according to the thermoelectric module of the present invention, the excellent bonding between the substrates and the electrodes and between the thermoelectric elements and the thermoelectric element may be implemented, thereby increasing the performance index and reliability of the thermoelectric module.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A method for manufacturing a thermoelectric module comprising:
forming each of first and second green laminates;
forming first and second preliminary electrodes by printing a conductive paste on each of the first and second green laminates;
disposing thermoelectric elements on any one of the first and second preliminary electrodes;
stacking the first and second green laminates in such a manner that the thermoelectric elements are interposed between the first and second preliminary electrodes; and
firing the stacked first and second green sheet laminates, thereby forming the first and second electrodes, and first and second ceramic substrates, and simultaneously bonding the first ceramic substrate to the first electrode, the first and second electrodes to the thermoelectric elements, and the second ceramic substrate to the second electrode.

2. The method according to claim 1, further comprising forming a shrinkage constraint layer on an outer surface of each of the first and second green laminates, between forming the first and second green laminates and forming the first and second preliminary electrodes.

3. The method according to claim 2, wherein the shrinkage constraint layer is removed after firing the stacked first and second green laminates.

4. The method according to claim 2, wherein the stacked first and second green laminates may be fired by a pressurizing/firing process.

5. The method according to claim 1, wherein, in forming the first and second green laminates, the shrinkage constraint layer is interposed between the stacked green sheets for each of the first and second green laminates.

6. The method according to claim 1, wherein each of the first and second green laminates is provided with first and second grooves in which the first and second preliminary electrodes are buried, between forming the first and second green laminates and forming the first and second preliminary electrodes.

7. The method according to claim 1, wherein the conductive paste includes Sn, and may further include any one of Cu, Au, Ag, Bi, Ni, Sb, and Zr.

8. A thermoelectric module comprising:
first and second ceramic substrates which face each other;
first and second electrodes which are interposed between the first and second ceramic substrates and are bonded on inside surfaces of the first and second ceramic substrates by themselves, the first and second electrodes being stacked in a single layer; and
thermoelectric elements which are interposed between the first and second electrodes and are bonded to the first and second electrodes by self-bonding of the first and second electrodes.

9. The thermoelectric module according to claim 8, wherein the inner surfaces of the first and second ceramic substrates each are provided with grooves to bury the first and second electrodes.

10. The thermoelectric module according to claim 8, wherein each of the first and second electrodes includes Sn, and further includes any one of Cu, Au, Ag, Bi, Ni, Sb, and Zr.

11. The thermoelectric module according to claim 8, wherein the first and second ceramic substrates have outside surfaces each of which has a shrinkage constraint layer formed thereon.

12. The thermoelectric module according to claim 8, wherein each of the shrinkage constraint layers are provided between the ceramic substrates.

13. The thermoelectric module according to claim 12, wherein the shrinkage constraint layer includes at least one of Al₂O₃, MgO, ZrO₂, and TiO₂.

14. The thermoelectric module according to claim 8, wherein each of the first and second ceramic substrates is formed with ceramic sheets stacked in multiple layers.
